(19) United States
(12) Patent Application Publication
(10) Pub. No.: US 2025/0218868 A1
(43) Pub. Date: Jul. 3, 2025

(54) SELF-ALIGNED INTERCONNECT FEATURES WITH FLOATING DIELECTRIC STRUCTURE

(71) Applicant: Intel Corporation, Santa Clara, CA (US)

(72) Inventors: Sudipto Naskar, Portland, OR (US); Christopher J. Jezewski, Portland, OR (US); Akshit Peer, Hillboro, OR (US); Ananya Dutta; Jiun-Ruey Chen, Hillsboro, OR (US); Matthew V. Metz, Portland, OR (US); Mauro J. Kobrinsky, Portland, OR (US); Bryce C. Walker, Canby, OR (US); Dominic Esan, Hillsboro, OR (US); Weimin C. Han, Portland, OR (US)

(73) Assignee: Intel Corporation, Santa Clara, CA (US)

(21) Appl. No.: 18/397,247

(22) Filed: Dec. 27, 2023

(51) Int. Cl. H01L 21/768; H01L 23/522; H01L 23/528

(52) U.S. Cl. CPC H01L 21/76897; H01L 21/76879; H01L 23/5226; H01L 23/5283

(57) ABSTRACT

An integrated circuit device includes (i) a first interconnect feature extending within a first dielectric material, and (ii) a second interconnect feature extending within the first dielectric material, and landing on the first interconnect feature. The integrated circuit device further includes a layer having a first section and a second section, wherein the layer includes a second dielectric material that is compositionally different from the first dielectric material. An opening between the first section and the second section is above, and vertically aligned to, the first interconnect feature. The second interconnect feature extends through the opening. In an example, each of the first section and the second section is vertically separated from the first interconnect feature by at least 2 nanometers (nm). In an example, a dielectric constant of the second dielectric material is higher than a dielectric constant of the first dielectric material by at least 5%.

### FIELD OF DISCLOSURE

The present disclosure relates to integrated circuits, and more particularly to interconnect features, such as conductive vias and lines, within integrated circuits.

### BACKGROUND

Fabrication of microelectronic devices involves forming electronic components on microelectronic substrates, such as silicon wafers. These electronic components may include transistors, resistors, capacitors, and other active and passive devices, with overlying interconnect features (e.g., vias and lines) to route signals and power to and/or from the electronic components. Scaling of microelectronic devices results in high density and lower pitch of scaled interconnect features. There remain a number of non-trivial challenges with respect to scaled interconnect features.

### BRIEF DESCRIPTION OF THE DRAWINGS

FIG. 1A illustrates a cross sectional view of a section of an integrated circuit (IC) including a first layer having a plurality of sections and comprising a first dielectric material, wherein the plurality of sections of the first layer are on a second layer comprising a second dielectric material, and wherein at least one of the plurality of sections of the first layer is vertically separated from an interconnect feature by the second layer, in accordance with an embodiment of the present disclosure.

FIG. 1B illustrates a vertical alignment of an opening between two adjacent ones of the plurality of sections of the first layer of the IC of FIG. 1A with a corresponding interconnect feature below the opening, in accordance with an embodiment of the present disclosure.

FIG. 2 illustrates a flowchart depicting a method of forming an IC, in accordance with an embodiment of the present disclosure.

FIGS. 3A, 3B, 3C, 3D, 3E, 3F, 3G, 3H, 3I, and 3J illustrate cross-sectional views of an IC (such as the IC of FIG. 1A) in various stages of processing according to the methodology of FIG. 2, in accordance with an embodiment of the present disclosure.

FIG. 4 illustrates a computing system implemented with integrated circuit structures having one or more interconnect features formed using the techniques disclosed herein, in accordance with some embodiments of the present disclosure.

These and other features of the present embodiments will be understood better by reading the following detailed description, taken together with the figures herein described. In the drawings, each identical or nearly identical component that is illustrated in various figures may be represented by a like numeral. For purposes of clarity, not every component may be labeled in every drawing. Furthermore, as will be appreciated, the figures are not necessarily drawn to scale or intended to limit the described embodiments to the specific configurations shown. For instance, while some figures generally indicate straight lines, right angles, and smooth surfaces, an actual implementation of the disclosed techniques may have less than perfect straight lines and right angles (e.g., curved or tapered sidewalls and round corners), and some features may have surface topography or otherwise be non-smooth, given real-world limitations of fabrication processes. Further still, some of the features in the drawings may include a patterned and/or shaded fill, which is merely provided to assist in visually identifying the different features. In short, the figures are provided merely to show example structures.

### DETAILED DESCRIPTION

Provided herein is an integrated circuit structure including fully self-aligned interconnect features, where an upper interconnect feature lands on, and is vertically self-aligned with a lower interconnect feature. The upper and lower interconnect features extend within a first dielectric material. In an example, the self-alignment is achieved at least in part using a plurality of sections of a layer of second dielectric material that is etch selective with respect to the first dielectric material, and that is deposited using an area selective deposition (ASD) scheme. In an example, two adjacent ones of the plurality of sections of the layer of the second dielectric material define an opening therebetween, where the opening is vertically self-aligned with the lower interconnect feature there below. The upper interconnect feature extends through this opening, and lands on the lower interconnect feature. In an example, the plurality of sections is vertically separated from a plurality of lower interconnect features (which includes the above described lower interconnect feature, on which the upper interconnect feature lands). The plurality of sections of the layer of second dielectric material is floating within the first dielectric material, and is at least in part surrounded by the first dielectric material. Maintaining a vertical separation between the plurality of sections of the layer and the plurality of lower interconnect features results in elimination, or at least reduction of fringe capacitance between two adjacent ones of the plurality of lower interconnect features through a corresponding one of the plurality of sections. Numerous variations, embodiments, and applications will be apparent in light of the present disclosure.

### General Overview

As previously noted, non-trivial issues remain with respect to implementing scaled interconnect features. For example, with scaling of the interconnect features (such as conductive vias and conductive lines) having tight pitch, it is becoming increasingly difficult to align a first upper interconnect feature to a first lower interconnect feature, such that the first upper interconnect feature lands on the first lower interconnect feature. A self-aligned process can be employed, in which the upper interconnect feature is self-aligned to the lower interconnect feature. In an example, a self-alignment process uses a dielectric material, such as a high-k dielectric material, which is used as an etch stop layer and which facilitates aligning the first upper interconnect feature to the first lower interconnect feature. However, fringe capacitance may develop between the first lower interconnect feature and a laterally adjacent second lower interconnect feature, through the high-k dielectric material, thereby degrading performance of the integrated circuit device.

Accordingly, techniques are provided herein to form an IC that includes fully self-aligned interconnect features extending through a first dielectric material, where the self-alignment is achieved using a plurality of sections of a layer comprising a second dielectric material, wherein the plurality of sections of the second dielectric material are vertically separated from a plurality of lower interconnect features. In an example, to achieve etch selectively and/or for one or more other process requirements, the second dielectric material may have relatively high dielectric constant (such as are high-k dielectric material). The above described vertical separation between the plurality of sections of high-k second dielectric material and the plurality of lower interconnect features results in elimination, or at least reduction in fringe capacitance between two adjacent ones of the plurality of lower interconnect features through the second dielectric material. In an example, the second dielectric material is deposited using an area selective deposition (ASD) process, which results in the self-alignment of the interconnect features.

In an example, an integrated circuit (IC) includes a lower interconnect layer comprising a plurality of lower interconnect features extending within the first dielectric material, and an upper interconnect layer comprising a plurality of upper interconnect features extending within the first dielectric material. Each upper interconnect feature lands on, and is self-aligned to, a corresponding one of the lower interconnect feature. The upper and lower interconnect layers can be within a back end of line (BEOL) section of the IC, in an example. The upper and lower interconnect layers have tight pitch for the interconnect features therewithin, such as a pitch that is at most 50 nanometers (nm), or at most 40 nm, or at most 30 nm, or at most 25 nm, or at most 20 nm, for example.

The integrated circuit further comprise a plurality of sections of a discontinuous layer comprising second dielectric material floating within the upper interconnect layer. The second dielectric material is elementally and/or compositionally different from the first dielectric material. For example, the second dielectric material has a dielectric constant is higher than a dielectric constant of the first dielectric material. In such an example, the second dielectric material is a high-k material.

In one embodiment, two adjacent sections of the layer define a corresponding opening therebetween, where each such opening is vertically self-aligned to a corresponding lower interconnect feature. For example, a first opening is between a first section and a second section, where the first opening is above, and vertically self-aligned to, a first lower interconnect feature; a second opening is between the second section and a third section, where the second opening is above, and vertically self-aligned to, a second lower interconnect feature; and so on.

Self-aligning each such opening with a corresponding lower interconnect feature ensures that if and when a corresponding upper interconnect feature is formed, the upper interconnect feature extends through the opening and is also resultantly self-aligned to the corresponding lower interconnect feature. For example, a first upper interconnect feature extending through the first opening is self-aligned to, and lands on, the first lower interconnect feature that is vertically below the first opening.

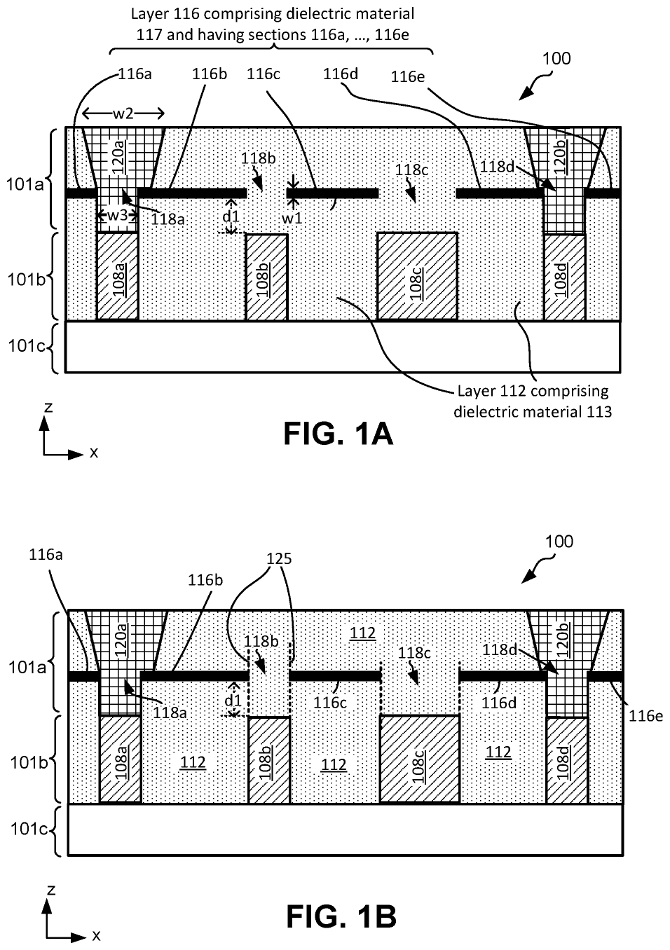

The plurality of sections of the dielectric material is vertically separated from the plurality of lower interconnect features by a distance d1 (e.g., see FIG. 1A). If the distance d1 is zero or less than a threshold value (such as less than 1 nm), then, for example, the high-k second dielectric material of the plurality of sections of the layer would be sufficiently close to the lower interconnect features. In such an example, the presence of the high-k second dielectric material sufficiently close and between the first and second lower interconnect features may increase or result in fringe capacitance between the first and second lower interconnect features, resulting in performance degradation. However, because the vertical separation d1 is greater than a threshold value, there is sufficient vertical separation between the high-k second dielectric material and each of the first and second lower interconnect features. Accordingly, any such fringe capacitance between the first and second lower interconnect features is eliminated, or at least reduced, thereby improving the performance of the IC. The vertical separation d1 is at least 2 nm, or at least 3 nm, or at least 4 nm, or at least 5 nm, for example. In an example, the distance d1 ranges from 2-10 nm.

The second dielectric material of the plurality of sections of the layer floats within the first dielectric material, and is at least in part surrounded by the first dielectric material. This results in a floating dielectric-on-dielectric (DoD) structure, as described below.

Also described below are example techniques for forming the IC having the floating plurality of section of the layer of second dielectric material within the first dielectric material, where the plurality of sections of the layer of second dielectric material are deposited using an area selective deposition (ASD) process, resulting in the above described self-alignment. Numerous variations, embodiments, and applications will be apparent in light of the present disclosure.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the materials has an element that is not in the other material.

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. In particular, in some embodiments, such tools may be used to detect a lower interconnect feature extending within a first dielectric material, an upper interconnect feature extending within the first dielectric material and landing on the lower interconnect feature, and a first section and a second section of a layer comprising a second dielectric material that is compositionally different from the first dielectric material, wherein an opening between the first section and the second section is above the lower interconnect feature, wherein the upper interconnect feature extends through the opening, and wherein each of the first section and the second section is vertically separated from the first interconnect feature by at least 2 nanometers (nm) or at least 4 nm, for example. Such tools may be used to detect the first and second sections comprising the second dielectric material floating within the first dielectric material (e.g., at least in part surrounded by the first dielectric material). Numerous configurations and variations will be apparent in light of this disclosure.

### Architecture and Methodology

FIG. 1A illustrates a cross sectional view of a section of an integrated circuit (IC) 100 including a first layer 116 comprising a first dielectric material 117 and having a plurality of sections 116a, 116b, 116c, 116d, 116e that are on a horizontal plane, wherein the first plurality of sections 116a, . . . , 116e are on a second layer 112 comprising a second dielectric material 113, and wherein at least one of the first plurality of sections 116a, . . . , 116e (such as the section 116b) is vertically separated from an interconnect feature 108b by the second layer 112, in accordance with an embodiment of the present disclosure.

The IC 100 comprises an upper interconnect layer 101a, an intermediate interconnect layer 101b, and a lower interconnect layer 101c. Although only three such interconnect layers 101a, 101b, 101c are illustrated in FIG. 1A, the IC may include several such interconnect layers.

The upper interconnect layer 101a comprises a plurality of interconnect features 120a, 120b extending through a layer 112 of dielectric material 113. The intermediate interconnect layer 101b comprises a plurality of interconnect features 108a, 108b, 108c, 108d extending through the layer 112 of dielectric material 113. Thus, the layer 112 of dielectric material 113 is common to both the upper and intermediate interconnect layers 101a, 101b. The lower interconnect layer 101c may also include a layer of dielectric material, and one or more interconnect features extending therethrough. The interconnect layers 101a, 101b, 101c are within three corresponding metallization levels of the IC 100, and may be in a back end of line (BEOL) section of the IC 100, in an example.

The plurality of interconnect features 108a, 108b, 108c, 108d (e.g., an array of interconnect features) are arranged laterally adjacent to each other, and separated by the dielectric material 113 of the layer 112. The plurality of interconnect features 108a, 108b, 108c, 108d are on a horizontal plane, such that an upper surface of each of the plurality of interconnect features 108a, 108b, 108c, 108d are substantially coplanar, and similarly, a lower surface of each of the plurality of interconnect features 108a, 108b, 108c, 108d are substantially coplanar. Although four such interconnect features 108a, 108b, 108c, 108d are illustrated in the interconnect layer 101b, there are likely to be a higher number of such interconnect features in the interconnect layer 101b.

In an example, the interconnect features 108a, 108b, 108c, 108d (also referred to generally as interconnect features 108 in plural, and interconnect feature 108 in singular) comprise a liner or barrier layer, and a conductive fill material therewithin. The liner or barrier layer, in an example, prevents diffusion of the conductive fill material of an interconnect feature to an adjacent dielectric material, and/or facilitates better adhesion of the conductive fill material on walls of the dielectric material. Suitable materials for the liner or barrier layer include barrier layer refractory metals and alloys, cobalt, cobalt-nickel (CoNi), ruthenium-cobalt combination, molybdenum, nickel, manganese, titanium-tungsten (Ti), tantalum (Ta), tantalum-nitride (TaN), tantalum-silicon-nitride (TaSiN), titanium-nitride (TiN), titanium-silicon-nitride (TiSiN), tungsten (XV), tungsten-nitride (WN), tungsten-silicon-nitride (WiSiN), and/or combinations of such materials (e.g., a multi-lay stack of Ta/TaN). The conductive fill material comprises one or more metals and/or alloys thereof, e.g., copper, ruthenium, molybdenum, rhodium, iridium, cobalt, tungsten, nickel aluminide (NiAl), cobalt-tin combination (CoSn), platinum cobalt oxide (PtCoO2), palladium cobalt oxide (PdCoO2), molybdenum phosphide, niobium arsenide (NbAs), chromium aluminum carbide (Cr2AlC), manganese boride (MnB), cerium-cobalt-indium 5 (CeCoIn5), and/or other one or more conductive material. In an example, each of the interconnect features 108 is a conductive via (extending in the Z axis direction in FIG. 1A) or a conductive line (extending in the Y axis direction in FIG. 1A, in or out of the plane of the paper of FIG. 1A).

The interconnect layer 101a comprises the interconnect features 120a, 120b extending through the layer 112 of dielectric material 113. The interconnect feature 120a at least in part lands on the interconnect feature 108a, and the interconnect feature 120b at least in part lands on the interconnect feature 108d. As described below, a lower portion of the interconnect feature 120a is self-aligned to an upper portion of the interconnect feature 108a, and a lower portion of the interconnect feature 120b is self-aligned to an upper portion of the interconnect feature 108d. Although two such interconnect features 120a, 120b are illustrated in the interconnect layer 101a, there are likely to be a higher number of such interconnect features in the interconnect layer 101a, in an example.

The plurality of interconnect features 120a, 120b are arranged laterally adjacent to each other, separated by the dielectric material 113 of the layer 112, and on a horizontal plane, such that an upper surface of each of the plurality of interconnect features 120a, 120b are substantially coplanar, and similarly, a lower surface of each of the plurality of interconnect features 120a, 120b are substantially coplanar. In an example, the interconnect features 120a, 120b (also referred to generally as interconnect features 120 in plural, and interconnect feature 120 in singular) comprise a liner or barrier layer, and a conductive fill material therewithin, where examples of the liner or barrier layer and the conductive fill material have been described above. In an example, each of the interconnect features 120 is a conductive via or a conductive line.

As illustrated in FIG. 1A, a lateral dimension or width (e.g., along the horizontal plane) of an upper surface of the interconnect feature 120a is w2, and a lateral dimension or width (e.g., along the horizontal plane) of a lower surface of the interconnect feature 120a is w3. Note that in an example, a lateral dimension or width (e.g., along the horizontal plane) of an upper surface of the interconnect feature 108a is also w3. In an example, w2 is greater than or equal to w2. For example, w2 is at least 1.1×, or at least 1.2×, or at least 1.5×, or at least 2× of w3. In an example, w2 is between 1.1× to 2.5× of w3. Thus, the interconnect feature 120 may be tapered from the upper surface towards the bottom surface, in an example.

The IC 100 further comprises a layer 116 having a plurality of sections 116a, 116b, 116c, 116d, 116e, where the layer 116 comprises dielectric material 117. The sections 116a, . . . , 116e are discontinuous or separate from each other (e.g., any two of the sections 116a, . . . , 116e are physically separated by the layer 112. In an example, the dielectric material 117 of the sections 116a, 116b, 116c, 116d, 116e of the layer 116 is compositionally and/or elementally different from the dielectric material 113 of the layer 112. In an example, a dielectric constant of the dielectric material 117 is different from a dielectric constant of the dielectric material 113. In such an example, the dielectric constant of the dielectric material 117 is greater than the dielectric constant of the dielectric material 113 by at least 3%, or at least 5%, or at least 10%, or at least 20%, or at least 25%, or at least 30%, or at least 50%.

In an example, the layer 112 comprising the dielectric material 113 is an interlayer dielectric material (ILD). The dielectric material 113 comprises a relatively low-k dielectric material, in an example. In an example, the dielectric material 113 comprises silicon nitride (SiN), silicon oxide (SiO), silicon carbide (SiC), silicon oxycarbide (SiOC), silicon oxycarbonitride (SiOCN), and/or silicon oxynitride (SiON), e.g., include silicon and one or more of oxygen, carbon, or nitrogen. In an example, the dielectric material 113 is made porous, e.g., to decrease a dielectric constant of the dielectric material 113.

In an example, the dielectric material 117 is a high-k dielectric material, e.g., having dielectric constant greater than the dielectric constant of the dielectric material 113, and/or dielectric constant greater than that of silicon dioxide. The dielectric material 117 comprises hafnium oxide, hafnium silicon oxide, aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, for example.

In one embodiment, the dielectric material 117 is etch selective with respect to the dielectric material 113. For example, an etch process that etches the dielectric material 113 may not substantially etch the dielectric material 117.

As illustrated in FIG. 1A, the sections 116a, . . . , 116e of the layer 116 are on a same horizontal plane that is above, and vertically separated from, another horizontal plane including upper surfaces of the interconnect features 108a, . . . , 108d. Thus, the horizontal plane of lower surfaces of the sections 116a, . . . , 116e is at a distance d1 from the horizontal plane of upper surfaces of the interconnect features 10a8, . . . , 108d. For example, the lower surfaces of the sections 116a, 116b are vertically separated from the upper surface of the interconnect feature 108a by the distance d1, the lower surfaces of the sections 116b, 116c are vertically separated from the upper surface of the interconnect feature 108b by the distance d1, and so on. The distance d1 is at least 2 nm, or at least 3 nm, or at least 4 nm, or at least 5 nm, for example. In an example, the distance d1 ranges from 2-20 nm, or in the subranges of 5-20 nm, or 5-10 nm, or 10-20 nm.

Thus, the dielectric material 117 of the sections 116a, . . . , 116e of the layer 116 are shifted upward from the interconnect features 108, so as to maintain at least a threshold vertical separation between the sections 116a, . . . , 116e and the interconnect feature 108.

If the distance d1 is zero or less than a threshold value (such as less than 1 nm), then, for example, the high-k dielectric material 117 of the section 116b would be sufficiently close to the interconnect features 108a and 108b. In such an example, the presence of the high-k dielectric material 117 of the section 116b sufficiently close and between the two interconnect features 108a and 108b may increase or result in fringe capacitance between the interconnect features 108a and 108b, resulting in performance degradation. However, because in FIG. 1A the sections 116a, . . . , 116e are more than the threshold distance from the interconnect features 108a, . . . , 108d (e.g., at the vertical separation of d1), no such fringe capacitance between two adjacent interconnect features 108 (such as between interconnect features 108a and 108b) through any of the sections 116a, . . . , 116e results in the IC 100 of FIG. 1A, thereby improving the performance of the IC 100. Setting the distance d1 above a threshold level result in the floating sections 116a, . . . , 116e of the layer 116 being vertically separated from the interconnect features 108 by at least the threshold level, which eliminates or at least decreases fringe capacitance between two adjacent interconnect features (such as interconnect features 108b and 108c) through a corresponding one of the sections 116a, . . . , 116e (such as the section 116c).

As described below, the layer 116 comprising the sections 116a, . . . , 116e act as an etch stop layer, e.g., when the interconnect features 120a, 120b are being formed. Also, the sections 116a, . . . , 116e facilitate self-alignment of a lower portion of the interconnect feature 120a to an upper portion of the interconnect feature 108a, and a lower portion of the interconnect feature 120b to an upper portion of the interconnect feature 108d, for example.

Each of the sections 116a, . . . , 116e has a thickness or width of w1, where the width is measured in a vertical direction, such as the direction of vertical heights of the interconnect features 108, 120. Reducing the width w1 facilitates in further decrease or elimination of the above described fringe capacitance, although a minimum thickness may be needed to maintain integrity of the layer 116 during the below described etch processes, where the layer 116 acts as an etch stop layer. In one embodiment, the width w1 is at least 5 angstroms, or at least 1 nm, or at least 2 nm, or at least 3 nm, or at least 4 nm, or at least 5 nm. In one embodiment, the width w1 is at most 5 nm, or at most 10 nm, or at most 15 nm, or at most 20 nm. In an example, the width w1 ranges between 5 angstroms to 100 angstroms, or in the subranges of 5-50 angstroms, or 1-10 nm, or 2-5 nm.

In one embodiment, any two adjacent ones of the sections 116a, . . . , 116e define an opening therebetween. For example, an opening 118a is between the sections 116a, 116b; an opening 118b is between the sections 116b, 116c; an opening 118c is between the sections 116c, 116d; and an opening 118d is between the sections 116d, 116e.

FIG. 1B illustrates a vertical alignment of an opening 118 between two adjacent ones of the first plurality of sections 116a, . . . , 116d of the layer 116 with a corresponding interconnect feature 108 below the opening 118, in accordance with an embodiment of the present disclosure. Each opening 118 is above a corresponding one of the interconnect feature 108. For example, as described below, the sections 116a, . . . , 116e are self-aligned with respect to the interconnect features 108, such that each opening 118 is vertically above and vertically aligned with a corresponding one of the interconnect feature 108. For example, the opening 118a is vertically aligned to the interconnect feature 108a, the opening 118b is aligned to the interconnect feature 108b, the opening 118c is vertically aligned to the interconnect feature 108c, and the opening 118d is aligned to the interconnect feature 108d. For example, in FIG. 1B, imaginary dotted lines 125 extending vertically upwards (in the Z axis direction) from sidewalls of the interconnect feature 108b touch sidewalls of the opening 118b.

Such alignment is due to the processes for forming the IC 100, as described below, where the openings 118a, 118b, 118c, 118d are self-aligned to the corresponding interconnect features 108a, 108b, 108c, 108d, respectively. Similarly, the lower portion of the interconnect feature 120a is self-aligned to an upper portion of the interconnect feature 108a, and a lower portion of the interconnect feature 120b is self-aligned to an upper portion of the interconnect feature 108d. For example, the interconnect feature 120a is a self-aligned via, for being aligned to the interconnect feature 108a; and the interconnect feature 120b is a self-aligned via, for being aligned to the interconnect feature 108b.

Referring again to FIG. 1A, the dielectric material 113 of the layer 112 extends through each of openings 118b and 118c. On the other hand, the interconnect feature 120a extends through the opening 118a and lands on the interconnect feature 108a, and the interconnect feature 120b extends through the opening 118d and lands on the interconnect feature 108d.

In one embodiment, the interconnect feature 120a is within a threshold distance (such as at most 2 nm, or at most 1 nm), and/or in contact with, each of the sections 116a and 116b. Similarly, the interconnect feature 120b is within a threshold distance (such as at most 2 nm, or at most 1 nm), and/or in contact with, each of the sections 116d and 116e. For example, the interconnect feature 120a comprises a barrier layer, and conductive fill material therewithin, wherein the barrier layer of the interconnect feature 120a is in contact with each of the sections 116d and 116e. For example, the layer 112 is absent between at least a part of each of the sections 116a, 116b and the interconnect feature 120a. Similarly, the layer 112 is absent between at least a part of each of the sections 116d, 116e and the interconnect feature 120b.

As illustrated in FIG. 1A, the dielectric material 117 of the section 116c is fully embedded within the dielectric material 113 of the layer 112. For example, the layer 112 fully surrounds the section 116c, and the section 116c floats within the layer 112. Thus, the layer 112 is on all sides of the section 116c. For example, each of an upper surface, a lower surface, and one or more side surfaces of the section 116c is in contact with the layer 112.

As also illustrated in FIG. 1A, the dielectric material 117 of each of the sections 116a, 116b, 116d, and 116e is partially embedded within the dielectric material 113 of the layer 112. For example, the layer 112 partially surrounds each of the sections 116a, 116b, 116d, 116e, and each of the sections 116a, 116b, 116d, and 116e partially floats within the layer 112. For example, at least a part of an upper surface and at least a part of a lower surface of the section 116b is in contact with the layer 112. At least another part of the upper surface and at least a part of one or more side surfaces of the section 116b is in contact with the interconnect feature 120a. Because the dielectric material 117 of the sections 116a, . . . , 116e of the layer 116 at least partially floats within the dielectric material 113 of the layer 112, the resultant structure is also referred to as a floating dielectric-on-dielectric (DoD) structure.

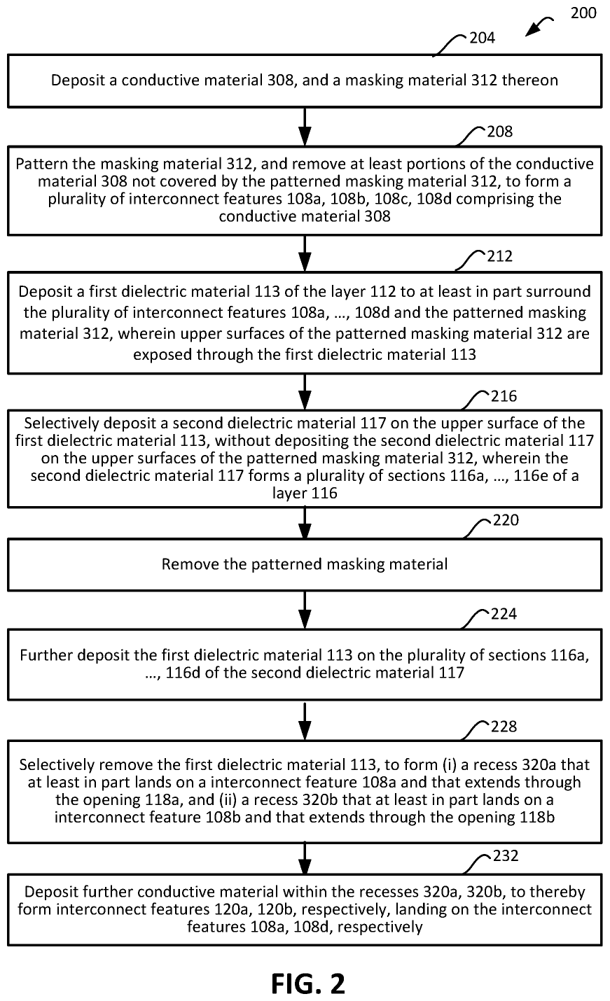

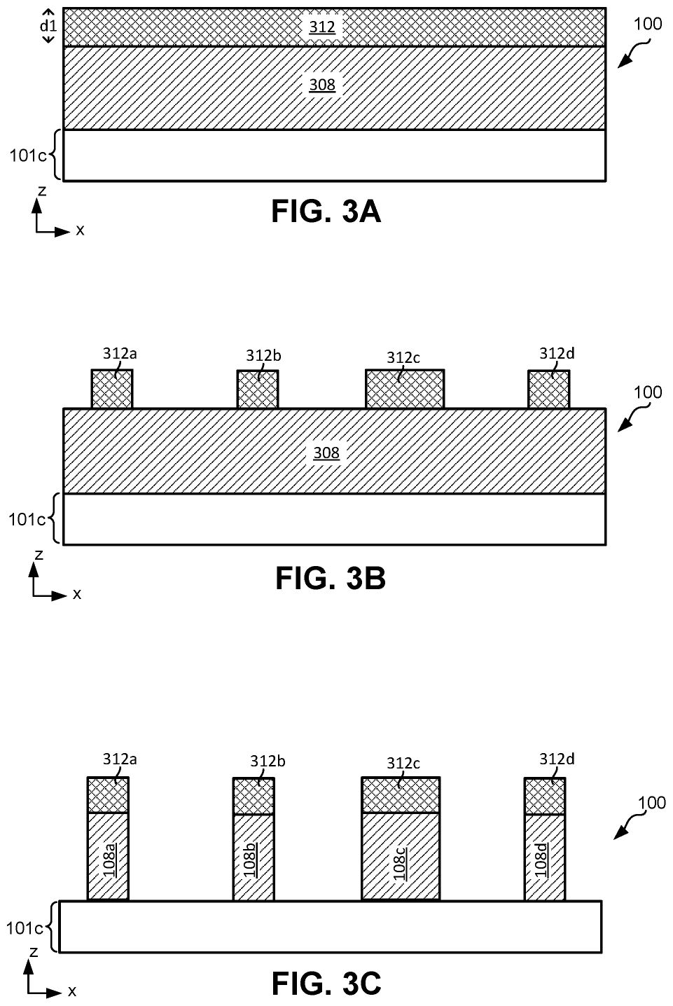

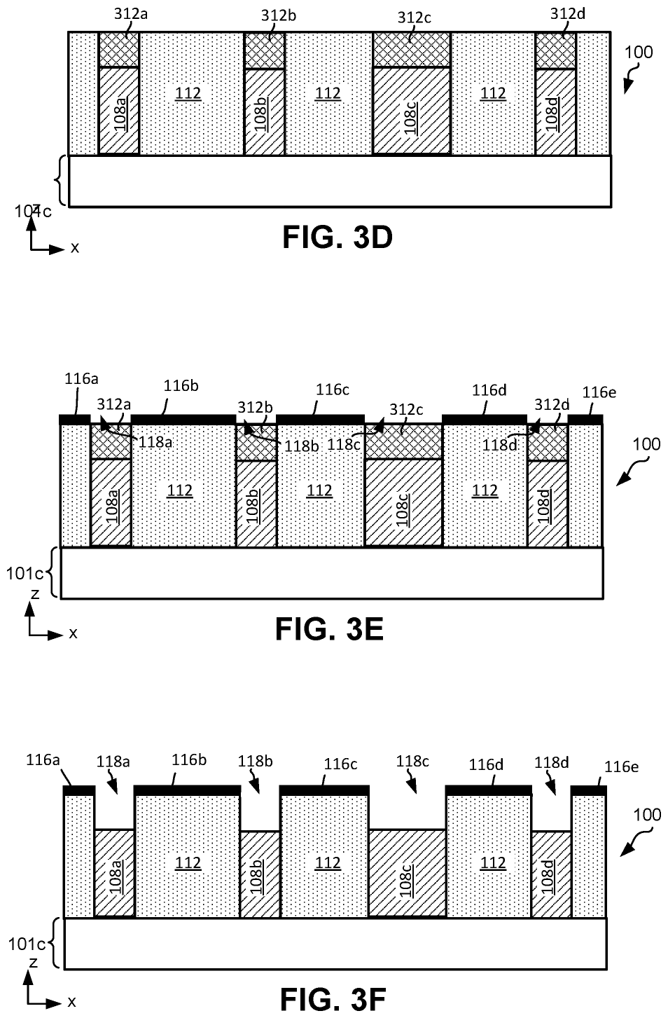

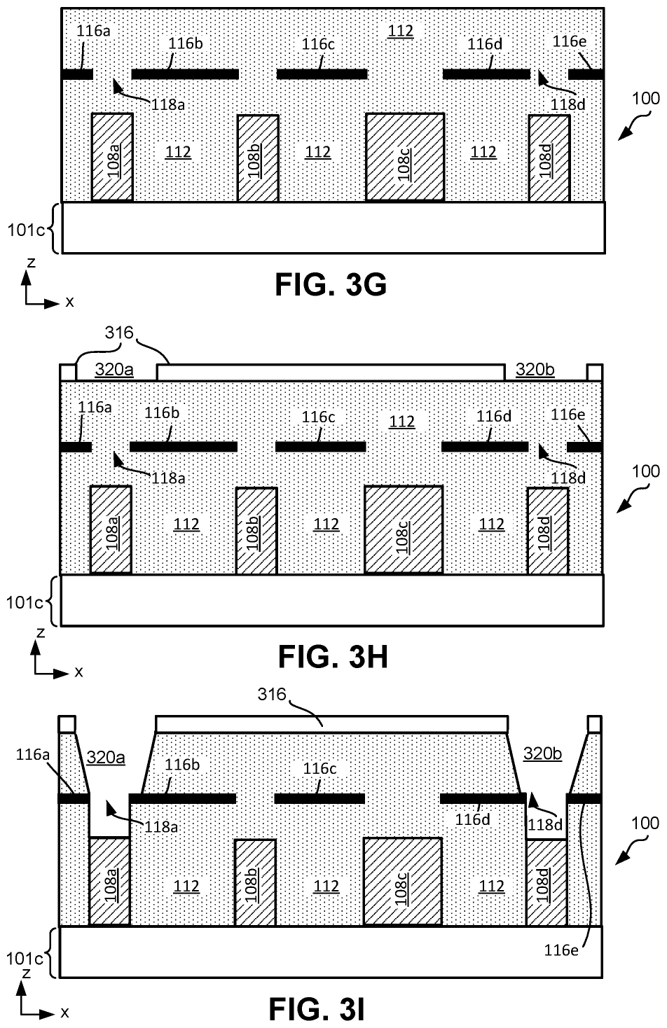

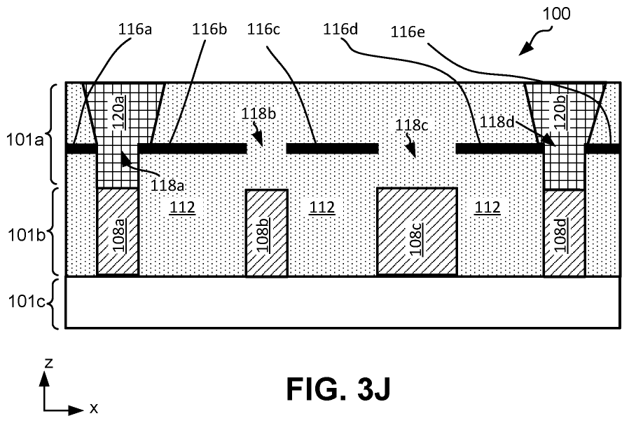

FIG. 2 illustrates a flowchart depicting a method 200 of forming an IC (such as the IC 100 of FIG. 1A), in accordance with an embodiment of the present disclosure. FIGS. 3A, 3B, 3C, 3D, 3E, 3F, 3G, 3H, 3I, and 3J illustrate cross-sectional views of an IC (such as the IC 100 of FIG. 1A) in various stages of processing according to the methodology 200 of FIG. 2, in accordance with an embodiment of the present disclosure. FIGS. 2 and 3A-3J will be discussed in unison.

The method 200 of FIG. 2 comprises, at 204, depositing a conductive material 308, and a masking material 312 thereon, as illustrated in FIG. 3A. The conductive material 308 is deposited on the above described lower interconnect layer 101c. Any deposition technique for depositing the conductive material may be used, such as chemical vapor deposition (CVD), physical vapor deposition (PVD), atomic layer deposition (ALD), vapor-phase epitaxy (VPE), molecular beam epitaxy (MBE), sputtering, or liquid-phase epitaxy (LPE), for example. Similarly, any deposition technique for depositing the masking material may be used, such as CVD, PVD, ALD, VPE, MBE, sputtering, or LPE, for example. The masking material 312 may be any hard mask material that etches at a lower rate than the conductive material 308, such as a metal based hard mask or a carbon based hard mask, in an example. The conductive material 308 may be any of the example conductive materials of the interconnect features 108 described above. Thus, subtractive patterning of the conductive material 308 is used to form the interconnect features 108a, . . . , 108d.

In an example, a height of the hard mask is d1, as illustrated in FIG. 3A. This height d1 eventually translates to the vertical separation d1 between any of the sections 116a, . . . , 116e and the corresponding interconnect feature 108, as described above with respect to FIG. 1A. As also described above, d1 is at least 2 nm, or at least 3 nm, or at least 4 nm, or at least 5 nm, for example. In an example, d1 ranges from 2-10 nm. Setting the distance d1 above the threshold level result in the floating sections 116a, . . . , 116e being vertically separated from the interconnect features 108 by at least the threshold level, which eliminates or at least decreases fringe capacitance between two adjacent interconnect features (such as interconnect features 108b and 108c) through the corresponding one of the sections 116a, . . . , 116e (such as the section 116c), as also described above.

The method 200 proceeds from 204 to 208. At 208, the masking material 312 is patterned, as illustrated in FIGS. 3B, e.g., to form islands 312a, 312b, 312c, 312d of masking materials 312. Also at 208, at least portions of the conductive material 308 not covered by the patterned masking material 312 are removed, to form a plurality of interconnect features 108a, 108b, 108c, 108d comprising the conductive material 308, e.g., as illustrated in FIG. 3C. An etch process may be employed to pattern the hard mask 312, and another etch process may be employed to remove the at least portions of the conductive material 308, where the masking material 312 is not substantially removed during the other etch process.

The method 200 proceeds from 208 to 212. At 212, a first dielectric material 113 of a layer 112 is deposited, to at least in part surround the plurality of interconnect features 108a, . . . , 108d and the patterned masking material 312, as illustrated in FIG. 3D. Any deposition technique for depositing the dielectric material 113 may be used, such as CVD, PVD, ALD, VPE, MBE, sputtering, or LPE. In an example, upper surfaces of the patterned masking material 312 are exposed through the dielectric material 113. In such an example, after deposition of the dielectric material 113, the dielectric material 113 is planarized, such that the upper surfaces of the patterned masking material 312 are exposed through the dielectric material 113.

The method 200 proceeds from 212 to 216. At 216, a second dielectric material 117 is selectively deposited on the upper surface of the first dielectric material 113, without depositing the second dielectric material 117 on the upper surfaces of the patterned masking material 312, as illustrated in FIG. 3E. In an example, the second dielectric material 117 forms a plurality of sections 116a, . . . , 116e of the layer 116.

Any selective deposition process, such as an area selective deposition (ASD) process, may be used to selectively deposit the second dielectric material 117 on the upper surface of the first dielectric material 113, without depositing the second dielectric material 117 on the upper surfaces of the patterned masking material 312. For example, a passivation material that adheres to or grows on the masking material 312 (but not on the first dielectric material 113) may be used to cover the masking material 312. Then the second dielectric material 117 may be deposited. In an example, the second dielectric material 117 can grow on the upper surface of the first dielectric material 113, and not on the passivation material. Subsequently, the passivation material is removed (e.g., etched), such that the second dielectric material 117 is on the upper surface of the first dielectric material 113, and not on the patterned masking material 312. The type of passivation material used may be based on the deposition and/or etch chemistry used, and/or on the material of the first and second dielectric materials 113, 117, and the masking material 312.

In an example, any two adjacent ones of the sections 116a, . . . , 116e of the second dielectric material 117 define an opening therebetween. For example, an opening 118a is between the sections 116a, 116b; an opening 118b is between the sections 116b, 116c; an opening 118c is between the sections 116c, 116d; and an opening 118d is between the sections 116d, 116e. Note that each opening 118 is self-aligned to a corresponding one of the interconnect feature 108, because the opening 118 is self-aligned to an island of the masking material 312, which is self-aligned to the corresponding interconnect feature there below.

The method 200 proceeds from 216 to 220. At 220, the patterned masking material 312 are removed, e.g., using an etch process, as illustrated in FIG. 3F. In an example, the plurality of sections 116a, . . . , 116e acts as etch stop layers during the removal process, such that the layer 112 of dielectric material 113 below the plurality of sections 116a, . . . , 116e of the layer 116 is not substantially removed during the removal process.

The method 200 proceeds from 220 to 224. At 224, the first dielectric material 113 is further deposited on the plurality of sections 116a, . . . , 116d of the second dielectric material 117 and on exposed upper surfaces of the interconnect features 108a, . . . , 108d, as illustrated in FIG. 3G, such that layer 112 is now below and above layer 116. Any deposition technique for depositing the dielectric material may be used, such as CVD, PVD, ALD, VPE, MBE, sputtering, or LPE, for example. At this point in the method 200, each of the sections 116a, . . . , 116e of the dielectric material 117 is floating within, and completely surrounded by, the layer 112 of the dielectric material 113.

The method 200 proceeds from 224 to 228. At 228, the first dielectric material 113 of layer 112 is selectively removed, to form (i) a first recess 320a that extends through the opening 118a between the section 116a and the section 116b of the second dielectric material 117 and at least partially lands on the interconnect feature 108a, and (ii) a second recess 320b that extends through the opening 118d between the section 116d and the section 116e of the second dielectric material 117 and at least partially lands on the interconnect feature 108d, as illustrated in FIGS. 3H and 3I.

For example, as illustrated in FIG. 3H, a mask 316 is formed above the dielectric material 113 of layer 112, and patterned, to form recesses 320a and 320b within the mask 316. Subsequently, as illustrated in FIG. 3I, the dielectric material 113 is removed through the openings 320a, 320b within the patterned mask 316. As illustrated in FIG. 3H, the recess 320a within the mask 316 is roughly aligned to opening 118a above the interconnect feature 108a, and the recess 320b within the mask 316 is roughly aligned to opening 118d above the interconnect feature 108d. In the example of FIGS. 3H and 3I, note that the alignment of the recess 320a with respect to opening 118a and the underlying interconnect feature 108a, as well as the alignment of the recess 320b with respect to opening 118d and the underlying interconnect feature 108d need not be perfect. One reason for this is that the packing or feature density above layer 116 is less than that density below layer 116, thus allowing for a greater margin of edge placement error. For instance, in the example of FIGS. 3H and 3I, there are four interconnect features (108a-d) below layer 116 and two interconnect features (not yet deposited into their respective recesses 320a and 320b) above layer 116. Further note that the upper width or surface area of the vias to be formed can be substantially wider (e.g., 1.2× wider, or more) than the lower width or surface area that will contact the underlying interconnect feature (108a and 108d, in this example). This increased area allows for lower contact resistance.

As further shown in FIG. 3I, when the dielectric material 113 of layer 112 is etched to extend the recess 320a within the layer 112, the sections 116a, 116b act as etch stop layers, and the opening 118a between the two section 116a, 116b is vertically self-aligned to the underlying interconnect feature 108a. Accordingly, although an upper portion of the recess 320a in FIG. 3I need not be fully vertically aligned to the interconnect feature 108a, the lower portion of the recess 320a is self-aligned to the upper portion of the interconnect feature 108a. Accordingly, the recess 320a lands on the interconnect feature 108a. Similarly, the lower portion of the recess 320b is vertically self-aligned to the upper portion of the interconnect feature 108d, and the recess 320b lands on the interconnect feature 108d.

The method 200 proceeds from 228 to 232. At 232, further conductive material is deposited within the recesses 320a, 320b, to thereby form interconnect features 120a, 120b, respectively, as illustrated in FIG. 3J. As described above with respect to FIG. 3I, lower portions of the recesses 310a, 310b are respectively aligned to the upper surfaces of the interconnect features 108a and 108d, respectively. Accordingly, the interconnect features 120a, 120b land on the interconnect features 108a, 108d, respectively. Thus, the interconnect feature 120a is self-aligned to the interconnect feature 108a, and hence, the interconnect feature 120a is also referred to as a self-aligned via. Similarly, the interconnect feature 120b is also a self-aligned via, for being aligned to the interconnect feature 108d. The resultant IC 100 of FIG. 3J is the IC 100 of FIG. 1A.

Note that the processes in method 200 are shown in a particular order for ease of description. However, one or more of the processes may be performed in a different order or may not be performed at all (and thus be optional), in accordance with some embodiments. Numerous variations on method 200 and the techniques described herein will be apparent in light of this disclosure.

### Example System

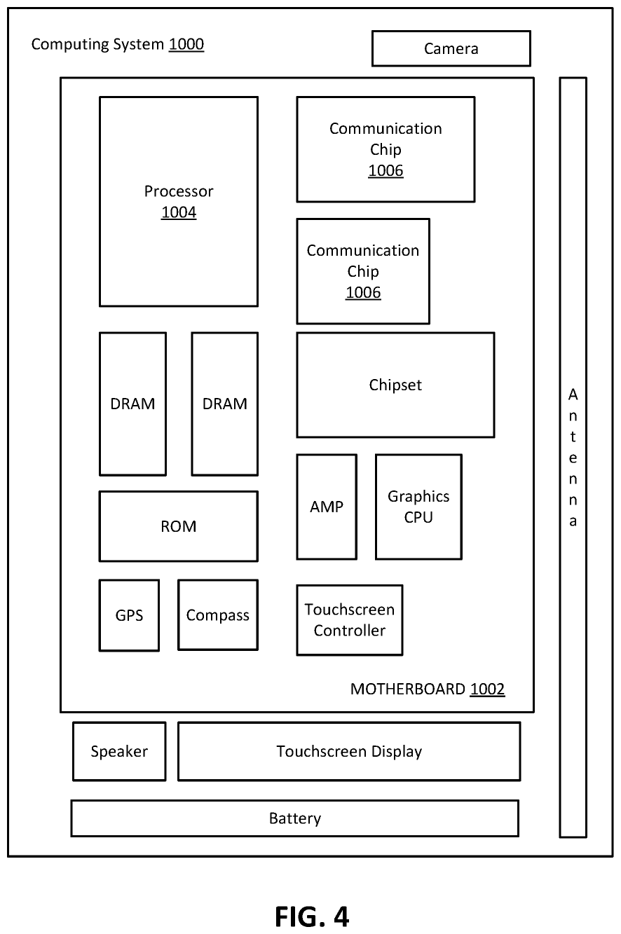

FIG. 4 illustrates a computing system 1000 implemented with integrated circuit structures and/or the interconnect features formed using the techniques disclosed herein, in accordance with some embodiments of the present disclosure. As can be seen, the computing system 1000 houses a motherboard 1002. The motherboard 1002 may include a number of components, including, but not limited to, a processor 1004 and at least one communication chip 1006, each of which can be physically and electrically coupled to the motherboard 1002, or otherwise integrated therein. As will be appreciated, the motherboard 1002 may be, for example, any printed circuit board, whether a main board, a daughterboard mounted on a main board, or the only board of system 1000, etc.

Depending on its applications, computing system 1000 may include one or more other components that may or may not be physically and electrically coupled to the motherboard 1002. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1000 may include one or more integrated circuit structures or devices formed using the disclosed techniques in accordance with an example embodiment. In some embodiments, multiple functions can be integrated into one or more chips (e.g., for instance, note that the communication chip 1006 can be part of or otherwise integrated into the processor 1004).

The communication chip 1006 enables wireless communications for the transfer of data to and from the computing system 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing system 1000 includes an integrated circuit die packaged within the processor 1004. In some embodiments, the integrated circuit die of the processor includes onboard circuitry that is implemented with one or more integrated circuit structures or devices formed using the disclosed techniques, as variously described herein. The term “processor” may refer to any device or portion of a device that processes, for instance, electronic data from registers and/or memory to transform that electronic data into other electronic data that may be stored in registers and/or memory.

The communication chip 1006 also may include an integrated circuit die packaged within the communication chip 1006. In accordance with some such example embodiments, the integrated circuit die of the communication chip includes one or more integrated circuit structures or devices formed using the disclosed techniques as variously described herein. As will be appreciated in light of this disclosure, note that multi-standard wireless capability may be integrated directly into the processor 1004 (e.g., where functionality of any chips 1006 is integrated into processor 1004, rather than having separate communication chips). Further note that processor 1004 may be a chip set having such wireless capability. In short, any number of processor 1004 and/or communication chips 1006 can be used. Likewise, any one chip or chip set can have multiple functions integrated therein.

In various implementations, the computing system 1000 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device or system that processes data or employs one or more integrated circuit structures or devices formed using the disclosed techniques, as variously described herein. Note that reference to a computing system is intended to include computing devices, apparatuses, and other structures configured for computing or processing information.

### Further Example Embodiments

The following clauses pertain to further embodiments, from which numerous permutations and configurations will be apparent.

Example 1. An integrated circuit device comprising: a first interconnect feature extending within a first dielectric material; a second interconnect feature extending within the first dielectric material, and landing on the first interconnect feature; and a layer having (i) a first section and (ii) a second section that is discontinuous with the first section, the layer comprising a second dielectric material that is compositionally different from the first dielectric material; wherein an opening between the first section and the second section is above the first interconnect feature; wherein the second interconnect feature extends through the opening; and wherein a lower surface of each of the first section and the second section is vertically separated from an upper surface of the first interconnect feature by at least 2 nanometers (nm).

Example 2. The integrated circuit device of example 1, wherein at least a part of an upper surface and at least a part of the lower surface of each of the first and second sections is in contact with the first dielectric material.

Example 3. The integrated circuit device of any one of examples 1-2, wherein no portion of the first dielectric material is between at least a portion of the second interconnect feature and the first section, and no portion of the first dielectric material is between at least another portion of the second interconnect feature and the second section.

Example 4. The integrated circuit device of any one of examples 1-3, further comprising: a third interconnect feature extending within the first dielectric material, and laterally adjacent to and separated from the first interconnect feature by the first dielectric material, with no other interconnect feature landing on the third interconnect feature; wherein the layer comprises a third section that is discontinuous with each of the first and second sections; wherein another opening between the second section and the third section is above, and vertically aligned to, the third interconnect feature; and where each of the lower surface of the second section and a lower surface of the third section is vertically separated from an upper surface of the third interconnect feature by at least 2 nm.

Example 5. The integrated circuit device of example 4, wherein the third section comprising the second dielectric material is fully surrounded on all sides by the first dielectric material.

Example 6. The integrated circuit device of any one of examples 1-5, wherein the opening between the first section and the second section is vertically aligned to the first interconnect feature.

Example 7. The integrated circuit device of any one of examples 1-6, wherein each of the first interconnect feature and the second interconnect feature is one of a conductive via or a conductive line.

Example 8. The integrated circuit device of any one of examples 1-7, wherein the first dielectric material is a low-k dielectric material, and the second dielectric material is a high-k dielectric material.

Example 9. The integrated circuit device of any one of examples 1-8, wherein a dielectric constant of the second dielectric material is higher than a dielectric constant of the first dielectric material by at least 5%.

Example 10. The integrated circuit device of any one of examples 1-9, wherein the lower surface of each of the first section and the second section is vertically separated from the upper surface of the first interconnect feature by at least 4 nm.

Example 11. The integrated circuit device of any one of examples 1-10, wherein the lower surface of each of the first section and the second section is vertically separated from the upper surface of the first interconnect feature by a vertical distance in the range of 5 nm to 20 nm.

Example 12. The integrated circuit device of any one of examples 1-11, wherein a thickness of each of the first section and the second section is in the range of 5 angstroms to 50 angstroms, and wherein the thickness is measured in a vertical direction and along a height of the first and second interconnect features.

Example 13. The integrated circuit device of any one of examples 1-12, wherein an upper surface of the second interconnect feature has a first width and a lower surface of the second interconnect feature has a second width, wherein the first and second widths are measured in a direction perpendicular to a direction of a height of the first and second interconnect features, and wherein the first width is least 1.2 times the second width.

Example 14. An integrated circuit device comprising: a first interconnect feature and a laterally adjacent second interconnect feature, each of the first and second interconnect features extending through and separated by a first dielectric material; a layer comprising a first section, a second section, and a third section, wherein the layer comprises a second dielectric material having a dielectric constant different from a dielectric constant of the first dielectric material, and wherein each of the first, second, third sections are discontinuous from other and are on a horizontal plane that is (i) above the first and second interconnect features, and (ii) vertically separated from the first and second interconnect features by at least 2 nanometers; wherein a first opening between the first and second sections is above the first interconnect feature, and a second opening between the second and third sections is above the second interconnect feature; and wherein at least one of the first, second, and third sections are surrounded on all sides by the first dielectric material.

Example 15. The integrated circuit device of example 14, further comprising: a third interconnect feature landing on the first interconnect feature, wherein the third interconnect feature is within 1 nm of each of the first section and the second section, wherein the third section is surrounded on all sides by the first dielectric material.

Example 16. The integrated circuit device of example 15, wherein the third interconnect feature is in contact with each of the first section and the second section.

Example 17. The integrated circuit device of example 14, wherein the dielectric constant of the second dielectric material is higher than the dielectric constant of the first dielectric material.

Example 18. A method comprising: depositing a conductive material, and a masking material thereon; patterning the masking material, and removing at least portions of the conductive material not covered by the patterned masking material, to form a plurality of interconnect features comprising the conductive material; depositing a first dielectric material to at least in part surround the plurality of interconnect features and the patterned masking material, wherein upper surfaces of the patterned masking material are exposed through an upper surface of the first dielectric material; selectively depositing a second dielectric material on the upper surface of the first dielectric material, without depositing the second dielectric material on the upper surfaces of the patterned masking material, wherein the second dielectric material forms a plurality of sections of a layer; and removing the patterned masking material.

Example 19. The method of example 18, further comprising: further depositing the first dielectric material on the plurality of sections of the layer of the second dielectric material, wherein the plurality of sections includes a first section, a second section, and a third section, wherein a first opening between the first and second sections is above a first interconnect feature of the plurality of interconnect features, and a second opening between the second and third sections is above a second interconnect feature of the plurality of interconnect features; selectively removing the first dielectric material, to form a recess that at least in part lands on the first interconnect feature and that extends through the first opening; and depositing, within the recess, further conductive material that at least in part lands on the first interconnect feature, to form a second interconnect feature above the first interconnect feature.

Example 20. The method of example 19, wherein during removal of the first dielectric material to form the recess, the layer including the first section and the second section acts as an etch stop layer, such that the recess extends through the first opening.

Example 21. The method of any one of examples 19-20, wherein the further conductive material deposited within the recess is in contact with each of the first section and the second section.

Example 22. The method of any one of examples 19-21, wherein the first section and the second section of the second dielectric material is at a vertical distance of at least 2 nanometers (nm) from an upper surface of the first interconnect feature.

The foregoing description of example embodiments has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto. Future filed applications claiming priority to this application may claim the disclosed subject matter in a different manner, and may generally include any set of one or more limitations as variously disclosed or otherwise demonstrated herein.

What is claimed is:

1. An integrated circuit device comprising:
a first interconnect feature extending within a first dielectric material;
a second interconnect feature extending within the first dielectric material, and landing on the first interconnect feature; and
a layer having (i) a first section and (ii) a second section that is discontinuous with the first section, the layer comprising a second dielectric material that is compositionally different from the first dielectric material;
wherein an opening between the first section and the second section is above the first interconnect feature;
wherein the second interconnect feature extends through the opening; and
wherein a lower surface of each of the first section and the second section is vertically separated from an upper surface of the first interconnect feature by at least 2 nanometers (nm).

2. The integrated circuit device of claim 1, wherein at least a part of an upper surface and at least a part of the lower surface of each of the first and second sections is in contact with the first dielectric material.

3. The integrated circuit device of claim 1, wherein no portion of the first dielectric material is between at least a portion of the second interconnect feature and the first section, and no portion of the first dielectric material is between at least another portion of the second interconnect feature and the second section.

4. The integrated circuit device of claim 1, further comprising:
a third interconnect feature extending within the first dielectric material, and laterally adjacent to and separated from the first interconnect feature by the first dielectric material, with no other interconnect feature landing on the third interconnect feature;
wherein the layer comprises a third section that is discontinuous with each of the first and second sections;
wherein another opening between the second section and the third section is above, and vertically aligned to, the third interconnect feature; and
where each of the lower surface of the second section and a lower surface of the third section is vertically separated from an upper surface of the third interconnect feature by at least 2 nm.

5. The integrated circuit device of claim 4, wherein the third section comprising the second dielectric material is fully surrounded on all sides by the first dielectric material.

6. The integrated circuit device of claim 1, wherein the opening between the first section and the second section is vertically aligned to the first interconnect feature.

7. The integrated circuit device of claim 1, wherein each of the first interconnect feature and the second interconnect feature is one of a conductive via or a conductive line.

8. The integrated circuit device of claim 1, wherein the first dielectric material is a low-k dielectric material, and the second dielectric material is a high-k dielectric material.

9. The integrated circuit device of claim 1, wherein a dielectric constant of the second dielectric material is higher than a dielectric constant of the first dielectric material by at least 5%.

10. The integrated circuit device of claim 1, wherein the lower surface of each of the first section and the second section is vertically separated from the upper surface of the first interconnect feature by at least 4 nm.

11. The integrated circuit device of claim 1, wherein the lower surface of each of the first section and the second section is vertically separated from the upper surface of the first interconnect feature by a vertical distance in the range of 5 nm to 20 nm.

12. The integrated circuit device of claim 1, wherein a thickness of each of the first section and the second section is in the range of 5 angstroms to 50 angstroms, and wherein the thickness is measured in a vertical direction and along a height of the first and second interconnect features.

13. The integrated circuit device of claim 1, wherein an upper surface of the second interconnect feature has a first width and a lower surface of the second interconnect feature has a second width, wherein the first and second widths are measured in a direction perpendicular to a direction of a height of the first and second interconnect features, and wherein the first width is least 1.2 times the second width.

14. An integrated circuit device comprising:
a first interconnect feature and a laterally adjacent second interconnect feature, each of the first and second interconnect features extending through and separated by a first dielectric material;
a layer comprising a first section, a second section, and a third section, wherein the layer comprises a second dielectric material having a dielectric constant different from a dielectric constant of the first dielectric material, and wherein each of the first, second, third sections are discontinuous from other and are on a horizontal plane that is (i) above the first and second interconnect features, and (ii) vertically separated from the first and second interconnect features by at least 2 nanometers;
wherein a first opening between the first and second sections is above the first interconnect feature, and a second opening between the second and third sections is above the second interconnect feature; and
wherein at least one of the first, second, and third sections are surrounded on all sides by the first dielectric material.

15. The integrated circuit device of claim 14, further comprising:
a third interconnect feature landing on the first interconnect feature, wherein the third interconnect feature is within 1 nm of each of the first section and the second section, wherein the third section is surrounded on all sides by the first dielectric material.

16. The integrated circuit device of claim 15, wherein the third interconnect feature is in contact with each of the first section and the second section.

17. The integrated circuit device of claim 14, wherein the dielectric constant of the second dielectric material is higher than the dielectric constant of the first dielectric material.

18. A method comprising:
depositing a conductive material, and a masking material thereon;
patterning the masking material, and removing at least portions of the conductive material not covered by the patterned masking material, to form a plurality of interconnect features comprising the conductive material;
depositing a first dielectric material to at least in part surround the plurality of interconnect features and the patterned masking material, wherein upper surfaces of the patterned masking material are exposed through an upper surface of the first dielectric material;
selectively depositing a second dielectric material on the upper surface of the first dielectric material, without depositing the second dielectric material on the upper surfaces of the patterned masking material, wherein the second dielectric material forms a plurality of sections of a layer; and
removing the patterned masking material.

19. The method of claim 18, further comprising:
further depositing the first dielectric material on the plurality of sections of the layer of the second dielectric material,
wherein the plurality of sections includes a first section, a second section, and a third section,
wherein a first opening between the first and second sections is above a first interconnect feature of the plurality of interconnect features, and a second opening between the second and third sections is above a second interconnect feature of the plurality of interconnect features;
selectively removing the first dielectric material, to form a recess that at least in part lands on the first interconnect feature and that extends through the first opening; and
depositing, within the recess, further conductive material that at least in part lands on the first interconnect feature, to form a second interconnect feature above the first interconnect feature.

20. The method of claim 19, wherein during removal of the first dielectric material to form the recess, the layer including the first section and the second section acts as an etch stop layer, such that the recess extends through the first opening.

21. The method of claim 19, wherein the further conductive material deposited within the recess is in contact with each of the first section and the second section.

22. The method of claim 19, wherein the first section and the second section of the second dielectric material is at a vertical distance of at least 2 nanometers (nm) from an upper surface of the first interconnect feature.
